(19) United States
(12) Patent Application Publication
(10) Pub. No.: US 2008/0121413 A1
(43) Pub. Date: May 29, 2008

(54) Method for manufacturing printed circuit boards

(76) Inventors: Sergio E. Cardona, Tucson, AZ (US); Jerry Apodaca, Tucson, AZ (US)

Correspondence Address: Benman, Brown & Williams;Ste. 2740, 2049 Century Park East, Los Angeles, CA, 90067, US

(21) Appl. No.: 11/986,849

(22) Filed: Nov. 26, 2007

Related U.S. Application Data
(60) Provisional application No. 60/861,351, filed on Nov. 27, 2006.

(51) Int. Cl. H05K 1/00; H01R 43/00

(52) U.S. Cl. 174/250; 29/825

(57) ABSTRACT

A printed circuit board. The novel printed circuit board includes a substrate, a layer of conductive material disposed on the substrate, and a solder mask layer disposed on the conductive layer, the solder mask layer including cutouts shaped as reference text and/or art. The conductive layer is etched to form traces for connecting electronic components to be mounted on the board in a desired pattern to form an electrical circuit and may include pads and lands to which the components are to be soldered. The solder mask layer is made from a material that resists wetting by solder and also includes cutouts in areas where the components are to be soldered to the conductive layer. The reference text and/or art includes readable information for assembling, testing, and/or repairing the circuit board, such as component part numbers, reference designators, pin one identifiers, component outlines, and test point identifiers.

### CROSS-REFERENCE TO RELATED APPLICATIONS

This application claims the benefit of U.S. Provisional Application No. 60/861,351, filed Nov. 27, 2006, the disclosure of which is hereby incorporated by reference.

This invention was made with Government support under Contract No. N00024-04-C-5344 awarded by the Department of the Navy. Accordingly, the U.S. Government may have certain rights in this invention.

### BACKGROUND OF THE INVENTION

1. Field of the Invention

The present invention relates to electronics. More specifically, the present invention relates to printed circuit boards.

2. Description of the Related Art

Printed circuit boards (PCBs), or printed wiring boards (PWBs), are commonly used in electronic systems to connect electronic components (such as integrated circuits, resistors, capacitors, etc.) in a desired pattern to form an electrical circuit. A PCB typically includes one or more conductive layers (typically of copper) separated by layers of insulating material (substrates) laminated together. The conductive layers are etched into conductive patterns, or traces, for connecting the electronic components, which are soldered to the board. The conductive layers may be selectively connected together by drilled holes called vias.

At locations where the electronic components are to be mounted, the PCB typically has flat conductive pads or lands, called solder pads. The components are soldered to the pads, usually by an automatic soldering process. Most PCBs also include a layer of a solder resist coating, or a solder mask, which covers areas that should not be soldered. The solder mask, which is typically a plastic polymer, resists wetting by solder and prevents solder from bridging between conductors and creating short circuits. The solder mask layer may also provide protection against environmental contaminants.

A PCB usually also includes line art and text that is printed on the top or bottom surface of the board by silk screening for providing readable information about component part numbers, reference designators, pin one identifiers, component outlines, test points, and other features helpful in assembling, testing, and/or repairing the circuit board. Unfortunately, this silk screening process can add an extra day to the fabrication cycle, increasing the cost of the PCB.

The fabrication of printed circuit boards is constantly being pushed by customer demands to produce smaller boards and at lower cost. At the same time, customer desires are to increase performance while becoming more manufacturable. Engineers have attempted to reduce cost by eliminating laminate cycles or reducing via counts. These approaches, however, may jeopardize circuit performance.

Hence, a need exists in the art for an improved system or method for fabricating printed circuit boards that reduces cost without jeopardizing performance or manufacturability.

### SUMMARY OF THE INVENTION

The need in the art is addressed by the printed circuit board of the present invention. The novel printed circuit board includes a substrate, a layer of conductive material disposed on the substrate, and a solder mask layer disposed on the conductive layer, the solder mask layer including cutouts shaped as reference text and/or art. The conductive layer is etched to form traces for connecting electronic components to be mounted on the board in a desired pattern to form an electrical circuit and may include pads and lands to which the components are to be soldered. The solder mask layer is made from a material that resists wetting by solder and also includes cutouts in areas where the components are to be soldered to the conductive layer. The reference text and/or art includes readable information for assembling, testing, and/or repairing the circuit board, such as component part numbers, reference designators, pin one identifiers, component outlines, and test point identifiers.

### BRIEF DESCRIPTION OF THE DRAWINGS

FIG. 1 is a simplified diagram of the different layers of a typical printed circuit board.

FIG. 2 is a top view of a typical printed circuit board, showing an illustrative silkscreen legend on the solder mask layer.

FIG. 3 is a simplified diagram of the different layers of a printed circuit board designed in accordance with an illustrative embodiment of the present invention.

FIG. 4 is a top view of a printed circuit board designed in accordance with an illustrative embodiment of the present invention, showing an illustrative solder mask layer with cutouts for reference text and art.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

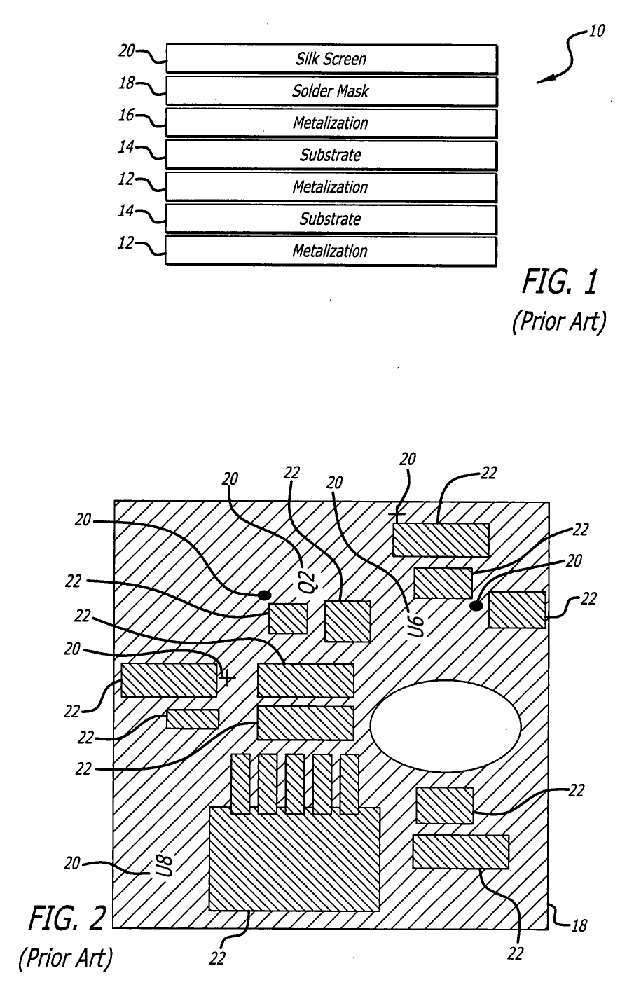

FIG. 1 is a simplified diagram of the different layers of a typical printed circuit board 10. The PCB 10 includes one or more conductive layers 12 (typically of copper) separated by layers of insulating material 14 (substrates) laminated together. The conductive layers 12 are etched to form traces for connecting the electronic components (not shown) to be mounted on the board 10 in a desired pattern to form an electrical circuit. One or more of the conductive layers 12 may be of solid metal for providing a ground plane and/or a power plane. The outer layer of metal 16 typically includes pads and lands to which the components are soldered.

A solder mask layer 18 is adhered to the outer layer 16 of the PCB 10. The solder mask 18, which is typically a plastic polymer, resists wetting by solder and prevents solder from bridging between conductors and creating short circuits. The solder mask 18 covers areas of the board 10 that should not be soldered and includes cutouts or openings in regions where the components are to be soldered to the board 10.

Most PCBs also include a layer of symbols, line art, and text 20 that is applied to the solder mask layer 18 by a silkscreen process. This silkscreen legend 20 provides readable information about component part numbers, reference designators, pin one identifiers, component outlines, test points, and other features helpful in assembling, testing, and/or repairing the circuit board. Typically, each solder pad has a silkscreen label (usually comprised of letters and numbers) printed next to the pad for identifying which component is to soldered to that pad. The pad may also have additional silkscreen symbols printed next to it for indicating the orientation of the component (for example, identifying the location of “pin one” of an integrated circuit).

FIG. 2 is a top view of a typical printed circuit board 10, showing an illustrative silkscreen legend 20 on the solder mask layer 18. The solder mask layer 18 includes cutouts 22 in regions where the electronic components are to be soldered to the board 10, leaving the solder pads of the outer conductive layer 16 exposed. As shown in the figure, the silkscreen legend 20 may include text indicating component part numbers, plus and/or minus signs for indicating the directionality of components (such as diodes or capacitors), and dots for indicating the locations of “pin one” of integrated circuits.

As discussed above, the silkscreen process used to add these reference designators can add an extra day to the fabrication time of a PCB, which may be about 20% of the total fabrication time of the board. The present invention provides a novel method for fabricating printed circuit boards that eliminates this silkscreen layer, thereby reducing the time and cost of producing a PCB. In accordance with the present teachings, the reference component part numbers and reference designators are integrated into the solder mask layer by thieving (or cutting out parts of) the solder mask layer instead of adding a layer of silkscreen.

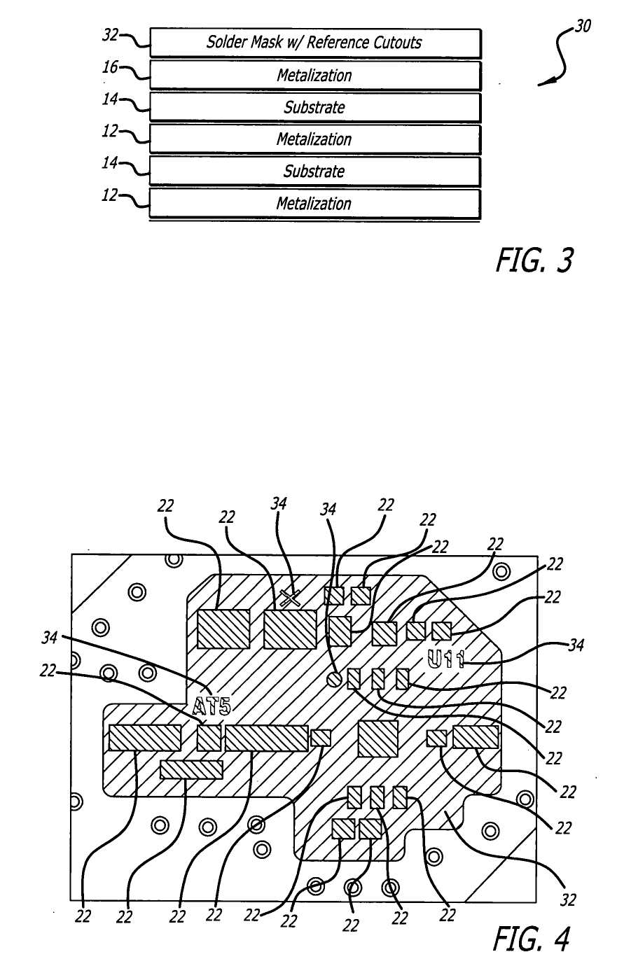

FIG. 3 is a simplified diagram of the different layers of a printed circuit board 30 designed in accordance with an illustrative embodiment of the present invention. The novel PCB 30 includes one or more conductive layers 12 (typically of copper) separated by layers of insulating material 14 (substrates) laminated together. The conductive layers 12 are etched to form traces for connecting the electronic components (not shown) to be mounted on the board 30 in a desired pattern to form an electrical circuit. One or more of the conductive layers 12 may be of solid metal for providing a ground plane and/or a power plane. The outer layer of metal 16 may include pads and lands to which the components are soldered.

A solder mask layer 32 is adhered to the outer layer 16 of the PCB 30 to prevent solder from bridging between conductors and creating short circuits. In accordance with the present teachings, the solder mask layer 32 is also adapted to provide reference text and/or art such as component part numbers, reference designators, pin one identifiers, component outlines, test point identifiers, and other features helpful in assembling, testing, and/or repairing the circuit board.

FIG. 4 is a top view of a printed circuit board 30 designed in accordance with an illustrative embodiment of the present invention, showing an illustrative solder mask layer 32 with cutouts for reference text and art. The solder mask layer 32 includes cutouts 22 in regions where the electronic components are to be soldered to the board 30, leaving the solder pads of the outer conductive layer 16 exposed.

In accordance with the present teachings, the solder mask layer 32 also includes cutouts 34 that form the reference text and art, using the metal of the outer layer 16 as a background. The reference text and art are carved out of the solder mask 32, forming cutouts 34 which can be easily readable if the color of the solder mask 32 contrasts with the color of the outer layer 16 of the board 30 (which shows through the cutouts 34). Solder mask material is typically green, which provides a strong contrast to the copper or gold that is typically used for the conductive layers. If the top layer 16 is not solid copper/gold, the substrate layer 14 under the outer conductive layer 16 may show through the cutouts 34. There may be a low contrast of reference text to the substrate material. Use of a different color of solder mask 32 may improve the contrast to increase the readability of the reference text.

The reference cutouts 34 in the solder mask layer 32 therefore provides the same function as the conventional silkscreen legend. The solder mask 32 should also provide its original function to protect against potential trace bridging. Designers should therefore be careful not to place the reference cutouts 34 in locations where solder might flow.

The reference cutouts 34 may be cut out of the solder mask layer 32 using the same techniques and at the same time as the solder area cutouts 22 are made. For example, this process may include having a CAD designer provide a layout indicating the locations of the cutouts (both the reference text cutouts 34 and the solder area cutouts 22), inputting the layout to a computer controlled machine that cuts away portions of a sheet of the solder mask material as indicated by the layout, and aligning and adhering the resulting solder mask sheet 32 to the PCB 30.

Thus, cropping the solder mask into letters, numbers, and art to form reference designators accomplishes the same function as the traditional silkscreen, but eliminates an additional step in the fabrication process, thereby saving time and cost. The reference designators are incorporated into the solder mask layer, eliminating the need for a designer to create a separate silkscreen image. Thieving the solder mask to form the reference designators should take a CAD designer the same amount of time and effort as producing a silkscreen. By incorporating the reference text into the solder mask layer as described in the present teachings, engineers can therefore speed up the fabrication process of printed circuit boards, thereby cutting costs, without jeopardizing performance or manufacturability.

Thus, the present invention has been described herein with reference to a particular embodiment for a particular application. Those having ordinary skill in the art and access to the present teachings will recognize additional modifications, applications and embodiments within the scope thereof.

It is therefore intended by the appended claims to cover any and all such applications, modifications and embodiments within the scope of the present invention.

Accordingly,

What is claimed is:

1. A printed circuit board comprising:
a substrate;
a layer of conductive material disposed on said substrate; and
a solder mask layer disposed on said conductive layer, said solder mask layer including cutouts shaped as reference text and/or art.

2. The invention of claim 1 wherein said reference text and/or art includes readable information for assembling, testing, and/or repairing the circuit board.

3. The invention of claim 2 wherein said reference text includes component part numbers.

4. The invention of claim 2 wherein said reference text includes reference designators.

5. The invention of claim 2 wherein said reference text includes pin one identifiers.

6. The invention of claim 2 wherein said reference art includes component outlines.

7. The invention of claim 2 wherein said reference text includes test point identifiers.

8. The invention of claim 1 wherein said conductive layer is etched to form traces for connecting electronic components to be mounted on said board in a desired pattern to form an electrical circuit.

9. The invention of claim 1 wherein said conductive layer includes pads and lands to which electronic components are to be soldered.

10. The invention of claim 1 wherein said solder mask layer is made from a material that resists wetting by solder.

11. The invention of claim 10 wherein said solder mask layer also includes cutouts in areas where electronic components are to be soldered to said conductive layer.

12. The invention of claim 1 wherein said printed circuit board further includes one or more additional layers of conductive material separated by non-conductive substrates.

13. A method for fabricating a printed circuit board including the steps of:
providing a substrate;
adhering a layer of conductive material on said substrate;
cutting out reference text and/or art in a layer of solder mask material; and
adhering said solder mask layer to said conductive material.
